(19) United States
(12) Patent Application Publication
(10) Pub. No.: US 2017/0234992 A1
(43) Pub. Date: Aug. 17, 2017

(54) IMAGING APPARATUS AND MANUFACTURING METHOD THEREOF

(71) Applicant: Sony Semiconductor Solutions Corporation, Kanagawa (JP)

(72) Inventor: Shinji Miyazawa, Kanagawa (JP)

(73) Assignee: Sony Semiconductor Solutions Corporation, Kanagawa (JP)

(21) Appl. No.: 15/519,380

(22) PCT Filed: Sep. 11, 2015
(86) PCT No.: PCT/JP2015/004636

§ 371 Date: Apr. 14, 2017

(30) Foreign Application Priority Data
Oct. 23, 2014 (JP) 2014-216046

(51) Int. Cl. G01T 1/202; H01L 27/146

(52) U.S. Cl. CPC G01T 1/202; H01L 27/14663; H01L 27/14625; H01L 27/14685

(57) ABSTRACT

[Solution to Problem] An imaging apparatus includes a photoelectric conversion layer, a light guide layer, and a scintillator layer. The photoelectric conversion layer has a plurality of pixel regions configured to be capable of performing photoelectric conversion. The light guide layer has a convex region formed to be convex toward an opposite side of the photoelectric conversion layer for each of the pixel regions, and is formed on the photoelectric conversion layer. The scintillator layer is formed directly on the light guide layer.

### TECHNICAL FIELD

The present technology relates to an imaging apparatus capable of converting, for example, radiation into light and to a manufacturing method thereof.

### BACKGROUND ART

Conventionally, there is an imaging apparatus that converts radiation such as X-rays into light, detects the light with a photodetector arranged for each pixel, and captures an image.

For example, a radiation imaging apparatus described in Patent Literature 1 includes a photoelectric converter including a pixel transistor and a photodiode provided on a first substrate, and a lens array provided above the photoelectric converter via a protection film and a second substrate. A scintillator layer is disposed above the lens array via a planarization layer. (For example, see Abstract, Specification paragraph [0061] of Patent Literature 1). By using the lens array, light collection efficiency to the photodiode is improved.

Meanwhile, Patent Literature 2 discloses an X-ray solid-state detector including a scintillator layer having a condenser lens shape that is disposed above a photoelectric conversion device array via a low refractive index layer (for example, see Specification paragraph of Patent Literature 2).

### CITATION LIST

### Patent Literature

Patent Literature 1: Japanese Patent Application Laid-open No. 2012-159483

Patent Literature 2: Japanese Patent Application Laid-open No. 2009-222578

### DISCLOSURE OF INVENTION

### Technical Problem

In such an imaging apparatus, it is important to increase light collection efficiency. This is because the increased light collection efficiency can ensure luminance necessary for imaging with a smaller amount of radiation.

It is an object of the present technology to provide an imaging apparatus having improved light collection efficiency and a manufacturing method thereof.

### Solution to Problem

In order to achieve the object, an imaging apparatus according to the present technology includes a photoelectric conversion layer, a light guide layer, and a scintillator layer.

The photoelectric conversion layer has a plurality of pixel regions configured to be capable of performing photoelectric conversion.

The light guide layer has the convex region formed to be convex toward an opposite side of the photoelectric conversion layer for each of the pixel regions, and is provided on the photoelectric conversion layer.

The scintillator layer is provided so as to be formed directly on the light guide layer.

With such a configuration, the scintillator layer is formed directly on the light guide layer without forming additional layers such as a planarization layer between the light guide layer and the scintillator layer, and hence light generated in the scintillator layer directly enters the convex region that can collect light in the light guide layer. This can suppress light collection loss and increase the light collection efficiency.

The scintillator layer may have gaps provided along boundaries among the pixel regions.

With this structure, light inside the scintillator layer is reflected at an interface between a scintillator material and the gaps. Thus, the light collection efficiency is improved.

The convex region of the light guide layer may be a lens-shaped region.

The light guide layer may include a step-like region constituted by the convex region and a region excluding the convex region.

A material of the light guide layer may have a refractive index equal to or higher than a refractive index of a material of the scintillator layer. For example, the material of the light guide layer may have a refractive index of 1.6 to 2.0. In addition, the material of the scintillator layer may have a refractive index of 1.6 to 2.0.

The material of the light guide layer may be SiN, SiON, or an organic material.

A manufacturing method of an imaging apparatus, according to the present technology includes providing a light guide layer on a photoelectric conversion layer having a plurality of pixel regions configured to be capable of performing photoelectric conversion, the light guide layer having a convex region formed to be convex toward an opposite side of the photoelectric conversion layer for each of the pixel regions.

Then, a scintillator material is vapor-deposited on the light guide layer.

In accordance with the manufacturing method, the scintillator layer is formed by vapor-depositing the scintillator material directly on the light guide layer without forming additional layers such as the planarization layer between the light guide layer and the scintillator layer. This can omit a manufacturing process and reduce costs of the material.

### Advantageous Effects of Invention

As described above, the present technology realizes an imaging apparatus having improved light collection efficiency and a manufacturing method thereof.

It should be noted that the effects described here are not necessarily limitative and may be any of effects described in the present disclosure.

### BRIEF DESCRIPTION OF DRAWINGS

FIG. 1 is a cross-sectional view showing a structure of an imaging apparatus according to a first embodiment according to an embodiment of the present technology.

FIG. 2 is a cross-sectional view of the imaging apparatus shown in FIG. 1, in an enlarged state.

FIG. 3 shows a manufacturing method of the imaging apparatus.

FIG. 4 is a cross-sectional view showing a structure of an imaging apparatus according to a second embodiment according to an embodiment of the present technology.

### MODE(S) FOR CARRYING OUT THE INVENTION

### First Embodiment

(Configuration of Imaging Apparatus)

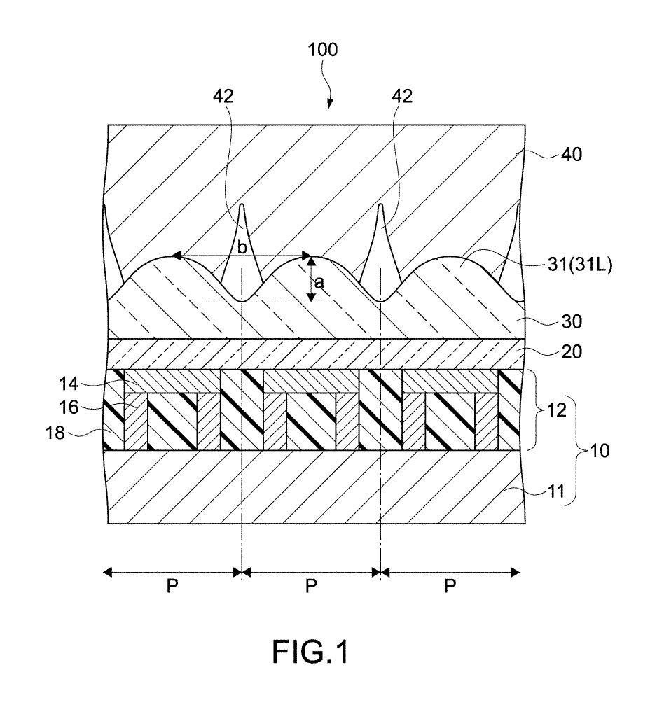

FIG. 1 is a cross-sectional view showing a structure of an imaging apparatus according to a first embodiment of the present technology. In FIG. 1, an imaging apparatus 100 includes a sensor substrate 10 having a photoelectric conversion layer 12, an insulation layer 20, a light guide layer 30, and a scintillator layer 40 in order from bottom.

The sensor substrate 10 has a plurality of pixel regions P, and includes the substrate 11 and the photoelectric conversion layer 12 provided on the substrate 11. The photoelectric conversion layer 12 includes photoelectric conversion elements 14 such as photodiodes, electrical connections 16, an insulator 18, and the like. The photoelectric conversion element 14 and the connection 16 are provided for each pixel region P.

The substrate 11 includes a circuit layer (not shown) connected to the connections 16, a support substrate supporting the circuit layer, and the like. The circuit layer provided on the substrate 11 also includes substantially the same circuit for each pixel region P. It is needless to say that the pixel regions P are in a two-dimensional array.

The sensor substrate 10 may have either one of a CCD (Charge Coupled Device) type structure and a CMOS (Complementary Metal-Oxide Semiconductor) type structure, for example.

The insulation layer 20 has a function to planarize the surface of the sensor substrate 10. Also, the insulation layer 20 has a function to increase adhesiveness of the light guide layer 30 to the sensor substrate 10. The insulation layer 20 is formed of a transparent material, for example, selected from a variety of materials. Typically, the insulation layer 20 is formed of the same material as the light guide layer 30 (where an inorganic material is used, SiN, SiON, or the like is used, as described later). It should be noted that the insulation layer 20 may be omitted.

The light guide layer 30 has a convex region 31 formed to be convex toward an opposite side of the photoelectric conversion layer 12, i.e., to face the scintillator layer 40 for each pixel region P. The convex region is a lens-like (convex lens-like) region where an on-chip lens is applied. In other words, the light guide layer 30 has a microlens array structure. Hereinafter, individual microlens will be referred to as a “lens portion” for convenience of description. The shape of a lens portion 31L may be spherical or aspherical.

For the material of the light guide layer 30, a transparent inorganic or organic material is used. Examples of the inorganic material include SiN and SiON. Examples of the organic material include phenol-based, fluorine-based, polyester-based, epoxy-based, and polyimide-based resin materials.

It should be noted that in the light guide layer 30 shown in FIG. 1, adjacent lens portions 31L are continuous. However, in the light guide layer 30, the adjacent lens portions 31L may be separate. In this case, it is desirable that the insulation layer 20 be not omitted and be provided as a base of the lens portions 31L, as shown in FIG. 1.

The scintillator layer 40 is provided so as to be formed directly on the light guide layer 30. Typically, the scintillator layer 40 is formed directly on the light guide layer 30 by vapor deposition, as described later. The scintillator layer 40 includes at least a phosphor material as a scintillator material. The phosphor material desirably absorbs energy of radiation, and has high efficiency to convert absorbed radiation energy into electromagnetic rays, for example, having a wavelength from 300 nm to 800 nm (electromagnetic rays (light) from ultraviolet light to infrared light, mainly including visible light). One example of the phosphor material includes one using CsI as a main agent and Tl or Na as an activator (augmenting agent) for increasing luminous efficiency or the like.

The scintillator layer 40 has gaps 42 provided along boundaries among the pixel regions P. In vapor deposition of the scintillator material, the scintillator material tends to be deposited as the surfaces of the lens portions 31L that serve as a base for vapor deposition become perpendicular to a crystal growth direction of the scintillator material (in an upper direction in FIG. 1). In other words, the scintillator material is unlikely to be deposited on portions among the adjacent lens portions 31L (in the vicinity of the boundaries among the pixel regions P), which are unsuitable for the base, in the crystal growth direction. Thus, the shown gaps 42 are formed after deposition time.

It should be noted that a transparent protection layer made of glass, acrylic, or the like may be formed on the scintillator layer 40.

The gaps 42 are formed such that scintillator materials on pixel regions P adjacent to each other are linked to each other at a predetermined height position from the surface of the lens portions 31L. The “predetermined height” is changed in a manner that depends mainly on curvature, a size, and the like of the lens portion 31L.

The material of the light guide layer 30 and the material of the scintillator layer 40 are selected such that the material of the light guide layer 30 has a refractive index (absolute refractive index) equal to or higher than that of the material of the scintillator layer 40. For example, the material of the light guide layer 30 has a refractive index of 1.6 to 2.0. The scintillator layer 40 also has a refractive index of 1.6 to 2.0.

As shown in FIG. 1, assuming that the height of the lens portion 31L (height from the bottom of the gaps 42 to the top of the lens portion 31L) is denoted by “a” and the pitch between the lens portions 31L is denoted by “b”, an aspect ratio is defined as a/b. The aspect ratio is 0.5 or more and 5 or less, for example. The aspect ratio may be 1 or more and 4 or less or 2 or more and 3 or less.

The curvature of the lens portion 31L (1/r (where r is a radius) is 0.1 or more and 2.0 or less, for example. For the narrower range, it may be 0.1 or more and 1.25 or less, 0.5 or more and 1.75 or less, or 1.0 or more and 1.5 or less.

(Manufacturing Method of Imaging Apparatus)

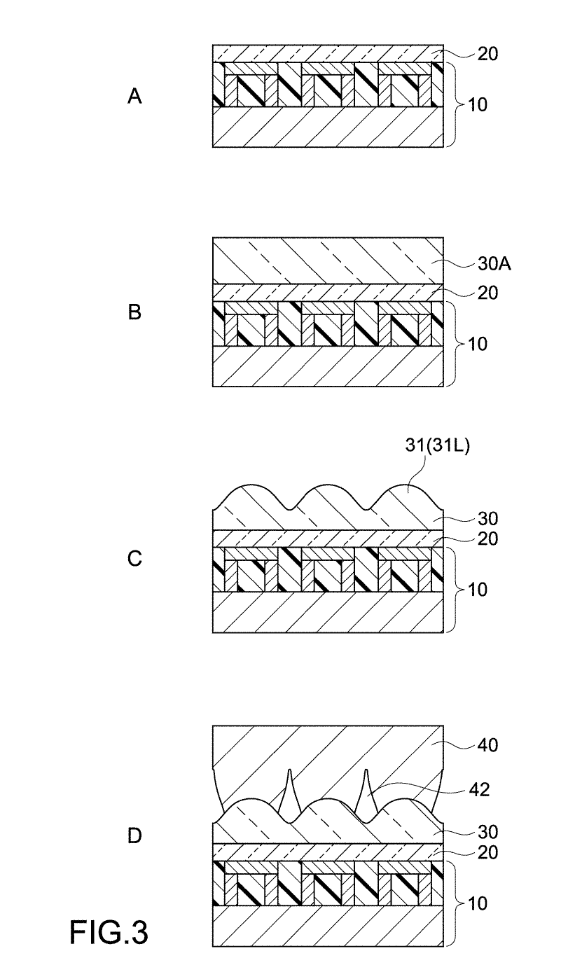

FIGS. 3A to 3D show a manufacturing method of the imaging apparatus 100. As shown in FIG. 3A, the sensor substrate 10 is prepared and the insulation layer 20 is formed on the sensor substrate 10. The insulation layer 20 may be coated or vapor-deposited. As described above, the insulation layer 20 does not need to be provided.

As shown in FIG. 3B, a film 30A of a light guide material for forming the light guide layer 30 is formed on the sensor substrate 10 (the insulation layer 20) by coating, vapor deposition, or sputtering. The “vapor deposition” may be either vacuum vapor deposition or atmospheric vapor deposition. The same applies “vapor deposition” of the scintillator layer 40.

As shown in FIG. 3C, the lens portion 31L is formed on the insulation layer 20 for each pixel region P (see FIG. 1). In the case where an organic material is used as the light guide material, a patterned resist material is reflowed by heat treatment, to thereby form the microlenses of the resist material.

In the case where an inorganic material is used as the light guide material, a film of the inorganic material is deposited, the microlenses of the resist material are formed on the inorganic film as described above, and anisotropic etching is then performed using the resist material as a mask. The microlenses of the inorganic material is thus formed.

Thereafter, as shown in FIG. 3D, the scintillator material is vapor-deposited and deposited on the light guide layer 30. In the vapor deposition process, the scintillator material is deposited on the surface of the lens portion 31L so as to form the gaps 42, as described above. Specifically, in the crystal grown process, the scintillator materials on pixel regions adjacent to each other are linked to each other. After the gaps 42 are formed, the scintillator material continues to deposit, to thereby form the scintillator layer 40.

(Actions of Imaging Apparatus)

Actions of the imaging apparatus 100 configured in the above-mentioned manner will be described. Radiation such as X-rays entering the scintillator layer 40 is converted into light by the scintillator material. The light generated in the scintillator layer 40 is collected at the lens portions 31L of the light guide layer 30 and is guided to the photoelectric conversion layer 12. The light entering the photoelectric conversion layer 12 is converted into an electrical signal. The radiation is not limited to the X-rays, and other radiation such as α rays and β rays may be applicable to the present technology in a manner that depends on the scintillator material.

### CONCLUSION

As described above, in the imaging apparatus 100 according to the embodiment, the scintillator layer 40 is formed directly on the light guide layer 30 without forming an additional layer such as the planarization layer between the light guide layer 30 and the scintillator layer 40. Therefore, the light generated in the scintillator layer 40 directly enters the lens portions 31L of the light guide layer 30. This suppresses light collection loss and improves the light collection efficiency. Thus, luminance necessary for imaging is ensured with a smaller amount of radiation.

For example, in the case where the planarization layer is provided between the condenser lens and the scintillator layer as a comparative example, the refractive index of the planarization layer is inevitably set to small because of the relationship between the refractive index of the condenser lens and the refractive index of the planarization layer. In this case, the refractive indices of the respective materials in the scintillator layer, the planarization layer, and the condenser lens is high, low, and high, respectively. Thus, the light entering the planarization layer and the light entering the condenser lens are easily reflected, which results in light collection loss. In contrast, in accordance with the present technology, the light collection loss can be suppressed as described above.

In this embodiment, the scintillator material is vapor-deposited directly on the light guide layer 30 without forming additional layers such as the planarization layer between the light guide layer 30 and the scintillator layer 40. This can omit a manufacturing process and reduce costs of the material.

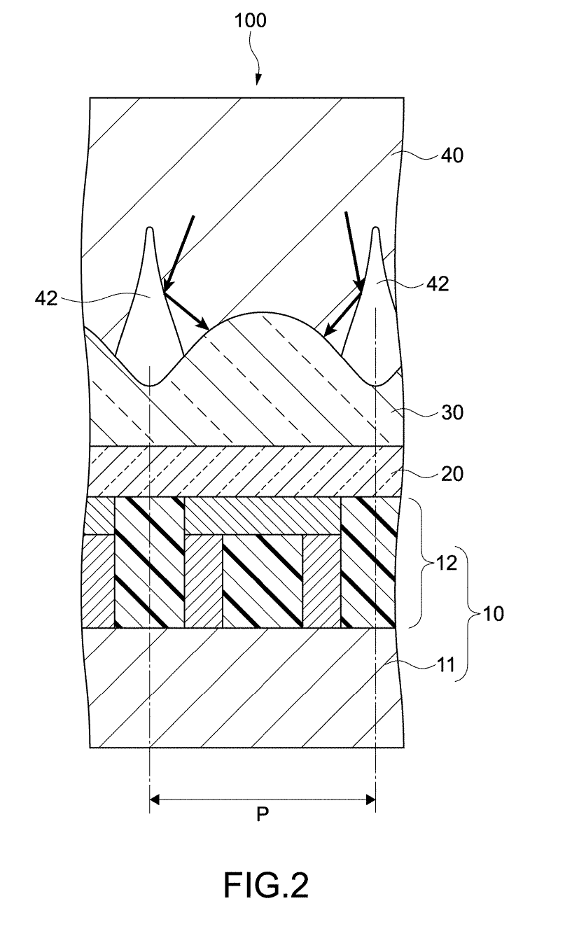

Also, in this embodiment, since the gaps 42 are provided, the following actions and effects are provided. As shown in FIG. 2, light generated in the scintillator layer 40 at the angle where total reflection occurs at the interface between the scintillator material and the gaps 42 in an arbitrary one pixel region P easily enters the light guide layer 30 in the same pixel region P. In other words, the total reflection of light easily occurs at the interface between the scintillator material and the gaps 42. Thus, the light collection efficiency can be further improved. Also, this reduces scattered light to the adjacent pixel regions P. Mixed color components generated by scattered light entering the adjacent pixel regions P can be decreased. Thus, the resolution is also improved.

In addition, since the gaps 42 are provided, the resolution can be increased without forming a member such as a division wall (partition) for dividing the pixel regions P in the scintillator layer 40, for example. Thus, the imaging apparatus is easy to manufacture and the manufacturing costs can be decreased.

### Second Embodiment

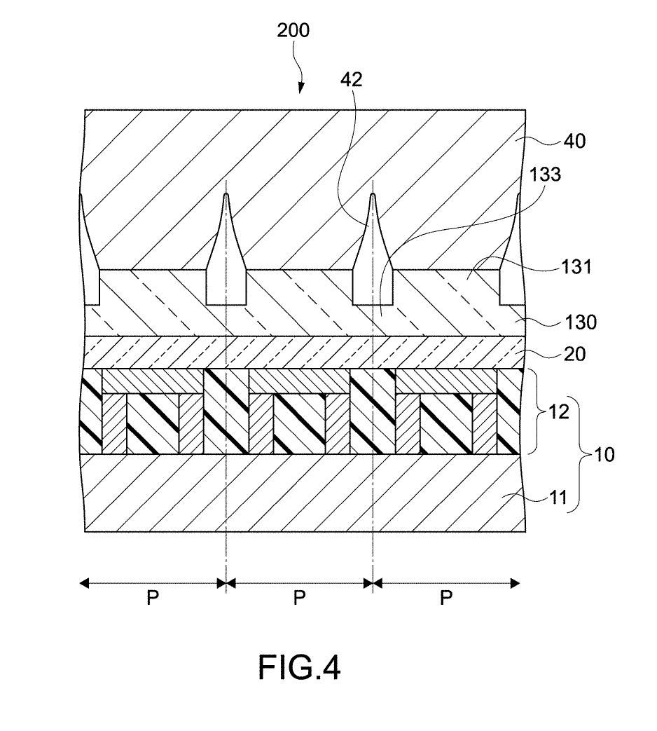

FIG. 4 is a cross-sectional view showing a structure of an imaging apparatus according to a second embodiment of the present technology. Hereinafter, elements substantially similar to the members, functions, and the like of the imaging apparatus 100 according to the first embodiment are denoted by identical symbols, descriptions thereof will be simplified or omitted, and different points will be mainly described.

In an imaging apparatus 200 according to this embodiment, the light guide layer 130 has a step-like region in place of the microlens structure. Specifically, a step is formed by a convex region 131 and a region 133 lower than the convex region 131 (region excluding the convex region 131). The surface of the convex region 131 in the light guide layer 30 is approximately flat. The light guide layer 30 is formed by film formation, photolithography, etching techniques, or the like.

The scintillator layer 40 is provided by crystal growth from the surface of the convex region 131. At a predetermined height position from the surface, scintillator materials on pixel regions P adjacent to each other are linked to each other. In this manner, the gap 42 including a groove region is formed.

Also, in this embodiment, the refractive index of the light guide layer 30 is set to be equal to or higher than the refractive index of the scintillator layer 40. The materials of the respective layers may be the same as the materials used in the first embodiment.

In accordance with the configuration of the imaging apparatus 200 according to this embodiment, actions and effects similar to those of the imaging apparatus 100 according to the above-described first embodiment can be obtained. The light collection efficiency of the imaging apparatus 200 may be slightly decreased in comparison with the imaging apparatus 100. However, no lens shape shown in FIG. 3C needs to be formed in the imaging apparatus 200 unlike the manufacturing method of the imaging apparatus 100. Thus, the manufacturing costs can be decreased.

### OTHER EMBODIMENTS

The present technology is not limited to the embodiments described above, and various other embodiments can be made.

In the above description, the convex regions 31 and 131 are described as the convex lens or step-like regions. However, the shapes of the convex regions may be wedge shapes tapered toward the scintillator layer 40 or may be trapezoid shapes (in cross-section). Alternatively, the shapes of the convex regions may be the shapes provided by combining at least two of a lens shape, a step-like shape, a wedge shape, and a trapezoid shape as long as they have convex shapes.

Although the imaging apparatuses 100 and 200 according to the above-described embodiments have the gaps 42, they are not indispensable. For example, in the case where the scintillator layer is formed by coating the light guide layer 30 or 130, an embodiment in which no gap is formed can be realized.

It is also possible to combine at least two characterizing parts of the characterizing parts of each of the above-mentioned embodiments.

The present technology can also have the following configurations.

(1) An imaging apparatus, including:

a photoelectric conversion layer having a plurality of pixel regions configured to be capable of performing photoelectric conversion;

a light guide layer provided on the photoelectric conversion layer, the light guide layer having a convex region formed to be convex toward an opposite side of the photoelectric conversion layer for each of the pixel regions; and a scintillator layer provided so as to be formed directly on the light guide layer.

(2) The imaging apparatus according to (1), in which

the scintillator layer has gaps provided along boundaries among the pixel regions.

(3) The imaging apparatus according to (1) or (2), in which

the convex region of the light guide layer is a lens-shaped region.

(4) The imaging apparatus according to (1) or (2), in which

the light guide layer includes a step-like region constituted by the convex region and a region excluding the convex region.

(5) The imaging apparatus according to any one of (1) to (4), in which

a material of the light guide layer has a refractive index equal to or higher than a refractive index of a material of the scintillator layer.

(6) The imaging apparatus according to (5), in which

the material of the light guide layer has a refractive index of 1.6 to 2.0.

(7) The imaging apparatus according to (5) or (6), in which

the material of the scintillator layer has a refractive index of 1.6 to 2.0.

(8) The imaging apparatus according to any one of (5) to (7), in which

the material of the light guide layer is SiN, SiON, or an organic material.

(9) A manufacturing method of an imaging apparatus, including:

providing a light guide layer on a photoelectric conversion layer having a plurality of pixel regions configured to be capable of performing photoelectric conversion, the light guide layer having a convex region formed to be convex toward an opposite side of the photoelectric conversion layer for each of the pixel regions; and

vapor-depositing a scintillator material on the light guide layer.

### REFERENCE SIGNS LIST

10 sensor substrate
11 substrate
12 photoelectric conversion layer
20 insulation layer
30, 130 light guide layer
31, 131 convex region
31L lens portion
40 scintillator layer
42 gap
100, 200 imaging apparatus

1. An imaging apparatus, comprising:
a photoelectric conversion layer having a plurality of pixel regions configured to be capable of performing photoelectric conversion;
a light guide layer provided on the photoelectric conversion layer, the light guide layer having a convex region formed to be convex toward an opposite side of the photoelectric conversion layer for each of the pixel regions; and
a scintillator layer provided so as to be formed directly on the light guide layer.

2. The imaging apparatus according to claim 1, wherein the scintillator layer has gaps provided along boundaries among the pixel regions.

3. The imaging apparatus according to claim 1, wherein the convex region of the light guide layer is a lens-shaped region.

4. The imaging apparatus according to claim 1, wherein the light guide layer includes a step-like region constituted by the convex region and a region excluding the convex region.

5. The imaging apparatus according to claim 1, wherein
a material of the light guide layer has a refractive index equal to or higher than a refractive index of a material of the scintillator layer.

6. The imaging apparatus according to claim 5, wherein
the material of the light guide layer has a refractive index of 1.6 to 2.0.

7. The imaging apparatus according to claim 5, wherein
the material of the scintillator layer has a refractive index of 1.6 to 2.0.

8. The imaging apparatus according to claim 5, wherein
the material of the light guide layer is SiN, SiON, or an organic material.

9. A manufacturing method of an imaging apparatus, comprising:
providing a light guide layer on a photoelectric conversion layer having a plurality of pixel regions configured to be capable of performing photoelectric conversion, the light guide layer having a convex region formed to be convex toward an opposite side of the photoelectric conversion layer for each of the pixel regions; and
vapor-depositing a scintillator material on the light guide layer.
